(19) United States
(12) Patent Application Publication
(10) Pub. No.: US 2020/0286757 A1
(43) Pub. Date: Sep. 10, 2020

(54) APPARATUS FOR ANNEALING SEMICONDUCTOR INTEGRATED CIRCUIT WAFERS

(71) Applicant: DSGI Technologies, Inc., San Jose, CA (US)

(72) Inventor: Jeffrey Edward Kowalski, San Jose, CA (US)

(73) Assignee: DSGI Technologies, Inc., San Jose, CA (US)

(21) Appl. No.: 16/813,251

(22) Filed: Mar. 9, 2020

Related U.S. Application Data
(60) Provisional application No. 62/815,499, filed on Mar. 8, 2019.

(51) Int. Cl. H01L 21/67; H05B 6/64; H05B 6/72

(52) U.S. Cl. CPC H01L 21/67115; H05B 6/72; H05B 6/642; H05B 6/6402

(57) ABSTRACT

An apparatus for annealing semiconductor integrated circuit wafers comprises a microwave energy source and a reactor housing. The microwave energy source is configured to generate microwave radiation having a first wavelength. The reactor housing is configured to receive a plurality of semiconductor integrated circuit wafers simultaneously. The reactor housing includes a top wall, a bottom wall, a left side wall, a right side wall, a front wall, and a back wall connected to one another to form a box-shaped internal chamber. Each wall is electrically connected to electrical ground and is water cooled. The walls of the internal chamber are spaced apart such that the microwave radiation forms a single mode within the internal chamber.

### RELATED APPLICATIONS

The current patent application claims priority benefit, with regard to all common subject matter, of earlier-filed U.S. Provisional Application titled “RESONATE FIELD WITH A FIXED MULTIMODE CAVITY”, Ser. No. 62/815,499, filed Mar. 8, 2019. The listed application is hereby incorporated by reference, in its entirety, into the current patent application.

### FIELD OF THE INVENTION

Embodiments of the current invention relate to equipment used in semiconductor integrated circuit wafer fabrication processes, specifically annealing of semiconductor integrated circuit wafers.

### BACKGROUND

Annealing of semiconductor integrated circuit wafers involves heating the thin films deposited or grown on the silicon substrates (wafers) in order to affect the structural or crystal properties of the thin films utilized to fabricate semiconductor integrated circuits. Affecting the structural, crystal properties and contaminants in these thin films may establish or adjust electrical properties of the integrated circuits. Also, controlling the temperature of a wafer to provide uniform heating across the area of the wafer is critical. Prior art apparatuses for annealing wafers include a reactor chamber which allows multiple modes of microwave radiation. These multiple mode chambers often do not heat the wafers uniformly and require large chamber sizes, which are not ideal for high-volume manufacturing. Furthermore, the apparatuses typically include a hot plate or heated pedestal on which the wafer is placed on to be heated. This hot plate or heated pedestal transfers the heat to the wafer through conduction. This indirect heating of the wafers may lead to longer annealing time, hot spots on wafer through poor contact to hot plates which causes non-uniformity across wafer and greater energy consumption.

### SUMMARY OF THE INVENTION

Embodiments of the current invention solve the above-mentioned problems and provide a distinct advance in the art of annealing semiconductor integrated circuit wafers, the invention solves the issue in question and also allows a substantial smaller chamber volume which is critical in semiconductor high volume manufacturing in regards to throughput, overall tool footprint and cost—overall the smaller chamber size vs the wafer size is important to be accepted in the semiconductor high volume manufacturing market. Specifically, embodiments of the current invention provide an apparatus which generates single mode microwave radiation that heats the wafers directly and uniformly. The apparatus comprises a microwave energy source and a reactor housing. The microwave energy source is configured to generate microwave radiation having a first wavelength. The reactor housing is configured to receive a plurality of semiconductor integrated circuit wafers simultaneously. The reactor housing includes a top wall, a bottom wall, a left side wall, a right side wall, a front wall, and a back wall connected to one another to form a box-shaped internal chamber. Each wall is electrically connected to electrical ground and is water cooled. The walls of the internal chamber are spaced apart such that the microwave radiation forms a single mode around the semiconductor integrated wafers within the internal chamber.

Another embodiment of the current invention provides an apparatus for annealing semiconductor integrated circuit wafers comprises a microwave energy source and a reactor housing. The microwave energy source is configured to generate microwave radiation having a first wavelength. The reactor housing is configured to receive a plurality of semiconductor integrated circuit wafers simultaneously. The reactor housing includes a top wall, a bottom wall, a left side wall, a right side wall, a front wall, and a back wall connected to one another to form a box-shaped internal chamber. Each wall is electrically connected to electrical ground and is water cooled. Each wafer is heated directly by the microwave radiation from the microwave energy source.

Yet another embodiment of the current invention provides an apparatus for annealing semiconductor integrated circuit wafers comprises a microwave energy source, a reactor housing, and a wafer support structure. The microwave energy source is configured to generate microwave radiation having a first wavelength. The reactor housing is configured to receive a plurality of semiconductor integrated circuit wafers simultaneously. The reactor housing includes a top wall, a bottom wall, a left side wall, a right side wall, a front wall, and a back wall connected to one another to form a box-shaped internal chamber. The walls of the internal chamber are spaced apart such that the microwave radiation forms a single mode within the internal chamber. Each wafer is heated directly by the microwave radiation from the microwave energy source. The wafer support structure includes a plurality of columns, with each column including a plurality of notches. Each semiconductor integrated circuit wafer is supported along an edge thereof by one notch of the respective columns.

This summary is provided to introduce a selection of concepts in a simplified form that are further described below in the detailed description. This summary is not intended to identify key features or essential features of the claimed subject matter, nor is it intended to be used to limit the scope of the claimed subject matter. Other aspects and advantages of the current invention will be apparent from the following detailed description of the embodiments and the accompanying drawing figures.

### BRIEF DESCRIPTION OF THE DRAWING FIGURES

Embodiments of the current invention are described in detail below with reference to the attached drawing figures, wherein:

FIG. 1 is an upper, forward perspective view of an apparatus, constructed in accordance with various embodiments of the invention, for annealing semiconductor integrated circuit wafers;

FIG. 2 is a lower, rearward perspective view of the apparatus;

FIG. 3 is a side perspective view of the apparatus from a forward angle with a side wall removed to expose an internal chamber in which the semiconductor integrated circuit wafers are annealed;

FIG. 4 is a side perspective view of the apparatus from a rearward angle;

FIG. 5 is a schematic view of the internal chamber and a plurality of semiconductor integrated circuit wafers illustrating a radiation of the semiconductor integrated circuit wafers;

FIG. 6 is a plot of a thermal reflectance of an inner surface of the walls surrounding the internal chamber vs. a wavelength of the radiation waves for the current invention and for prior art systems;

FIG. 7 is a plot of an electric field radiation pattern of the wafers at a rotation angle ϕ with three different values;

FIG. 8 is plot of a distribution of a wafer sheet resistance across four wafers, S1-S4, while the wafers are being annealed in a prior art system;

FIG. 9 is a plot of a normalized sheet resistance (Rs) vs. radial position for four wafers annealed in a prior art system;

FIG. 10 is a plot of a distribution of a wafer sheet resistance across four wafers, S1-S4, while the wafers are being annealed in the current invention; and

FIG. 11 is a plot of a normalized sheet resistance (Rs) vs. radial position for four wafers annealed in the current invention.

The drawing figures do not limit the current invention to the specific embodiments disclosed and described herein. The drawings are not necessarily to scale, emphasis instead being placed upon clearly illustrating the principles of the invention.

### DETAILED DESCRIPTION OF THE EMBODIMENTS

The following detailed description of the technology references the accompanying drawings that illustrate specific embodiments in which the technology can be practiced. The embodiments are intended to describe aspects of the technology in sufficient detail to enable those skilled in the art to practice the technology. Other embodiments can be utilized and changes can be made without departing from the scope of the current invention. The following detailed description is, therefore, not to be taken in a limiting sense. The scope of the current invention is defined only by the appended claims, along with the full scope of equivalents to which such claims are entitled.

Relational terms, such as “upper”, “lower”, “top”, “bottom”, “outer”, “inner”, “front”, “forward”, “back”, “rear”, etc., may be used throughout this description. These terms are used with reference to embodiments of the invention and the orientations thereof shown in the accompanying figures. Embodiments of the invention may be oriented in other ways. Therefore, the terms do not limit the scope of the current invention.

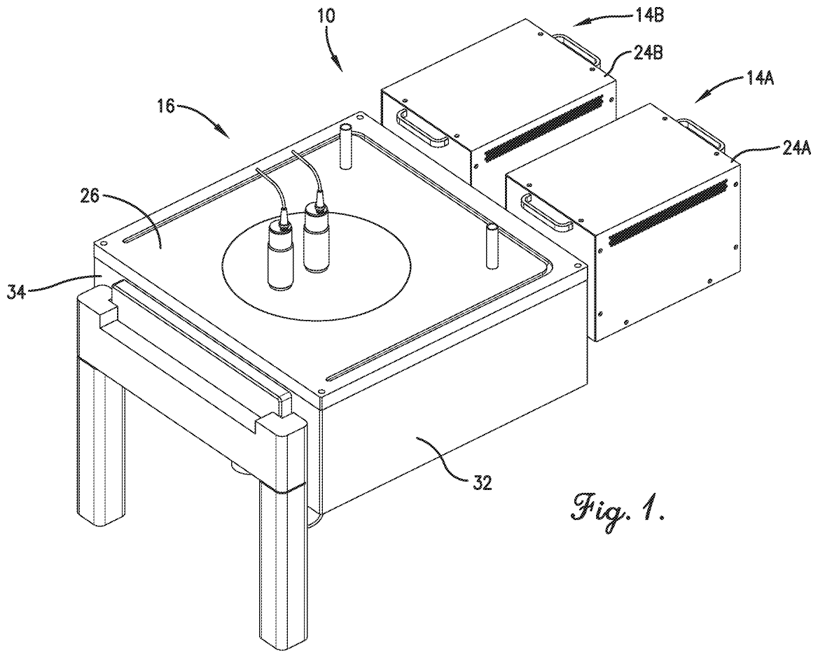

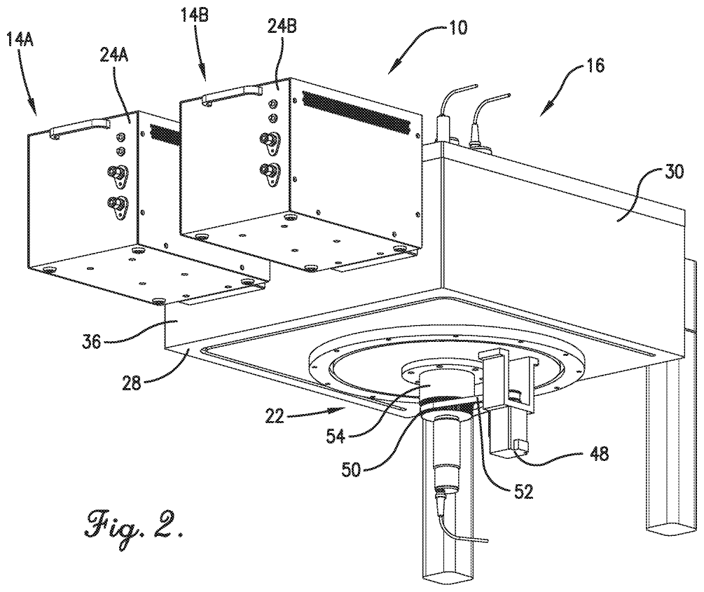

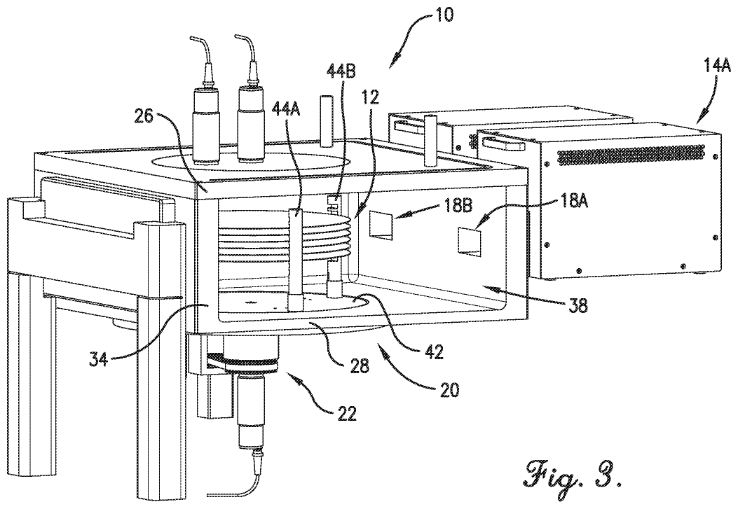

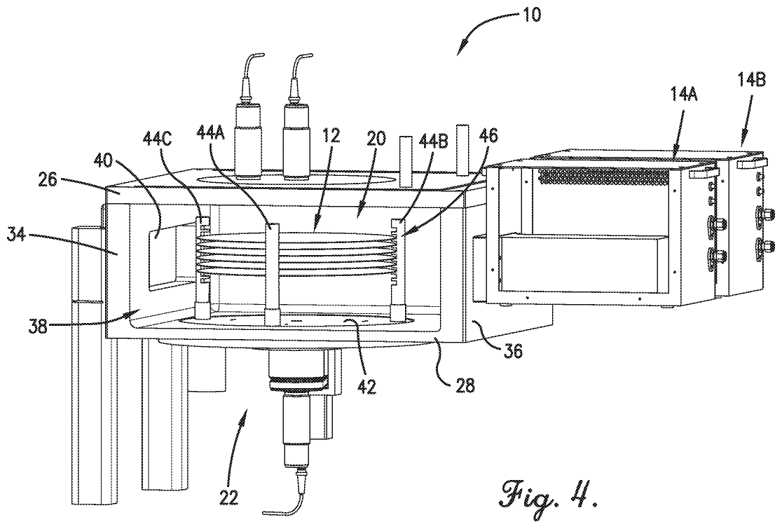

An apparatus 10, constructed in accordance with various embodiments of the current invention, for annealing semiconductor integrated circuit wafers 12 is shown in FIGS. 1-4. The apparatus 10 broadly comprises a microwave energy source 14, a reactor housing 16, a waveguide 18, a wafer support structure 20, and a wafer rotation unit 22. The wafers 12 may be formed from semiconductor material, such as silicon, doped silicon, silicon germanium, germanium, gallium nitride, gallium arsenide, or the like. The wafers 12 may have an exemplary thickness ranging from 0.5 millimeter (mm) to 1 mm, and may have a diameter of 150 mm, 200 mm, 300 mm, and so forth.

The microwave energy source 14 includes any one or more of a plurality of microwave radiation generators. In an exemplary microwave energy source 14, the microwave radiation generator includes a magnetron configured or operable to generate microwave radiation with a frequency of 915 megahertz (MHz), 2.45 gigahertz (GHz), 5.8 GHz, or others including solid state microwave sources between 915 MHz to 28 GHz. The microwave energy source 14 may be powered by an electric voltage, current, and/or power supply, which has an electrical ground reference. The microwave energy source 14 further includes its own housing 24—separate from, and external to, the reactor housing 16—in which the microwave radiation generator is housed. In various embodiments, the apparatus 10 may include a first microwave energy source 14A with housing 24A and a second microwave energy source 14B with housing 24B.

The reactor housing 16 includes a top wall 26, a bottom wall 28, a left side wall 30, a right side wall 32, a front wall 34, and a back wall 36 connected to one another to form a rectangular box with an internal chamber 38 or reactor space. Each wall 26, 28, 30, 32, 34, 36 includes an inner surface facing the internal chamber 38 and an outer surface. In various embodiments, an edge where any two adjacent walls 26, 28, 30, 32, 34, 36 intersect is rounded or filleted. In addition, a corner where any three adjacent walls 26, 28, 30, 32, 34, 36 intersect is rounded or filleted. The reactor housing 16 further includes a door 40 which aligns with and covers an opening in the front wall 34. The door 40 is opened to load wafers 12 into the internal chamber 38. One or more of the other walls 26, 28, 30, 32, 36 may include one or more openings. Some of the openings may allow for a gas inlet and a gas exhaust so gases such as nitrogen (N2), oxygen (O2), hydrogen, argon, and the like can be introduced into the internal chamber 38 during the annealing process. Furthermore, one or more of the openings may allow for the pressure within the internal chamber 38 to be adjusted.

Each wall 26, 28, 30, 32, 34, 36 is electrically conductive and has a bulk metal base, such as aluminum or stainless steel. In addition, each wall 26, 28, 30, 32, 34, 36 may be electrically connected to electrical ground—specifically the same electrical ground as is used for the microwave energy source 14. The inner surface of each wall 26, 28, 30, 32, 34, 36 is also polished and/or has a mirror finish. The inner surface of the top wall 26 and the bottom wall 28 also have a gold or silver coating or outer layer to reflect heat or infrared radiation. Furthermore, each wall 26, 28, 30, 32, 34, 36 is configured to be water cooled. The internal chamber 38 is sized such that the microwave radiation forms a single mode within the internal chamber 38. Specifically, the inner surfaces of the top wall 26 and the bottom wall 28 may be spaced apart from one another according to a wavelength of the microwaves generated by the microwave energy source 14. For example, if a 2.45 gigahertz (GHz) microwave energy source 14 is utilized, then the wavelength of the microwaves is approximately 122.4 mm (4.8 inches). Thus, the inner surfaces of the top wall 26 and the bottom wall 28 may be spaced apart by approximately 122.4 mm. Additionally, or alternatively, the top wall 26 and the bottom wall 28 may be positioned in relation to the stack of wafers 12 that are being processed. For example, the top wall 26 may be positioned such that its inner surface is a first distance away from the uppermost wafer 12 in the stack. An exemplary first distance may be approximately 20 mm. The bottom wall 28 may be positioned such that its inner surface is a second distance away from the lowest wafer 12 in the stack. An exemplary second distance may be approximately 20 mm. In various embodiments, the first distance and the second distance each may range from approximately 12.7 mm to approximately 76.2 mm.

The waveguide 18 generally couples the microwave energy source 14 to the reactor housing 16. The waveguide 18 includes a top wall, a bottom wall, a left side wall, and a right side wall connected to one another to form a tube with a rectangular cross section. A first end of the waveguide 18 is positioned in alignment with an opening on one of the walls of the housing 24 of the microwave energy source 14. A second opposing end of the waveguide 18 is positioned in alignment with an opening on the back wall 36 of the reactor housing 16 which accesses the internal chamber 38. The waveguide 18 guides microwave radiation from the microwave energy source 14 to the internal chamber 38. In various embodiments, the apparatus 10 may include a first waveguide 18A and a second waveguide 18B. The first waveguide 18 may guide microwave radiation from the first microwave energy source 14A to the internal chamber 38 through a first opening in the back wall 36. The second waveguide 18 may guide microwave radiation from the second microwave energy source 14A to the internal chamber 38 through a second opening in the back wall 36.

The wafer support structure 20 includes a plate 42 and a plurality of columns 44. The plate 42 has a circular or disc shape and is positioned above the bottom wall 28 of the housing 16. The plate 42 is configured or operable to rotate about a vertical axis, which is surface normal to the bottom wall 28. Each column 44 is generally elongated cylindrically shaped and is coupled to the plate 42 and is oriented upright, vertically, or surface normal to the plate 42. Each column 44 includes a plurality of notches 46, or cutouts, spaced apart from one another along a longitudinal axis of the column 44. Exemplary embodiments of the column 44 include nine notches 46, although greater or fewer are within the scope of the current invention. Each notch 46 extends radially inward, with a radial length of approximately 10 mm and a width of approximately 20 mm. A space between adjacent notches 46 is wide enough to accept an edge of a wafer 12. An exemplary wafer support structure 20 includes a first column 44A, a second column 44B, and a third column 44C. The columns 44 are positioned on the plate 42 adjacent to, and spaced apart along, the outer edge or circumference thereof. The columns 44 are located such that each column 44 supports the wafers 12 by contacting a respective point on a bottom surface along the outer edge or circumference of the wafer 12. The columns 44 may be selectively positioned to accommodate wafers 12 of different diameters. For example, the columns 44 may be manually repositioned on the plate 42, or the plate 42 may include tracks, rails, or grooves in which, or on which, the columns 44 may move to a new position.

The wafer rotation unit 22 includes a drive motor 48, a gear 50, a belt 52, and a drive shaft 54. The drive motor 48 may be embodied by one of a plurality of types of motors, such as alternating current (AC), direct current (DC), or the like, which includes a motor shaft that is rotated. The gear 50 is spaced apart from the motor shaft. The belt 52 is connected to the motor shaft and the gear 50 and mechanically and rotationally couples the motor shaft and the gear 50. The drive shaft 54 is connected to the gear 50 at a first end and is connected to the plate 42 at an opposing second end. Thus, rotation of the motor shaft causes rotation of the gear 50, through the belt 52, which in turns causes rotation of the plate 42, through the drive shaft 54.

The apparatus 10 may function as follows. Semiconductor wafers 12 are placed within the internal chamber 38 on the wafer support structure 20. The wafers 12 are placed such that each wafer 12 is positioned within a respective notch 46 of each column 44. Furthermore, the wafer 12 contacts each notch 46 on the bottom surface of the wafer 12 at a respective point along the edge of the wafer 12.

The number and the size of the wafers 12 in the internal chamber 38 determine a thermal load on the microwave energy source 14 and may have an effect on the annealing process. Larger numbers of wafers 12 and larger sizes of wafers 12 generally increase the thermal load and may have a detrimental effect on the annealing process. For large sized wafers 12, such as 300-mm wafers, between 3 and 6 wafers 12 in the internal chamber 38 during an annealing cycle may provide optimum results.

Before microwave radiation is applied, gases may be introduced into the internal chamber 38 and/or the pressure within the internal chamber 38 may be adjusted. Once the conditions are correct in the internal chamber 38, the microwave energy source 14 is activated and microwave radiation is introduced into the internal chamber 38. Since the size of the internal chamber 38—particularly the distance between the inner surfaces of the top wall 26 and the bottom wall 28, or the distances between the inner surface of the top wall 26 and the uppermost wafer 12 and the inner surface of the bottom wall 28 and the lowermost wafer 12—is proportional to, or varies with, the wavelength of the microwave radiation, the internal chamber 38 is a single mode chamber or reactor. As a result, the combination of the stack of wafers 12 being annealed, the top wall 26, and the bottom wall 28 form a slot plane antenna, which will form an electromagnetic field (or “single mode”) around the wafers 12 in which their impedance is matched to the microwave energy source 14 for an induction effect.

The electromagnetic field is omnidirectional and the polarization of the electromagnetic field is linear. In addition, the top wall 26 and the bottom wall 28 become a virtual waveguide that forms an electric field within the internal chamber 38. The wafers 12 are positioned within the electric field. Since the top wall 26 and the bottom wall 28 have a greater length and a greater width than the diameter of the wafers 12, the electric field is uniform, or distributed evenly, across the stack of wafers 12. Given that the internal chamber 38 is a single mode chamber or reactor, the wafers 12 are an impedance matched load for the microwave energy source 14 and are heated volumetrically. That is, each wafer 12 is heated directly by the microwave energy source 14 in a first-order reaction, as opposed to being heated indirectly in a second-order reaction, such as by each wafer 12 being placed in contact with a substrate which is heated by the microwave energy source 14, and the substrate transfers heat to each wafer 12. The microwave radiation also generates a magnetic field in the internal chamber 38 which induces eddy currents to flow within the wafers 12, additionally heating the wafers 12.

The wafers 12 are rotated by the wafer rotation unit 22 at a speed ranging from approximately 1 revolution per minute (rpm) to approximately 2 rpm. The rotation of the wafers 12 changes the radiation pattern generated by the wafers 12 and may affect the electric field within the internal chamber 38. The wafers 12 may be heated to a temperature ranging from approximately 550 degrees Celsius (C) to approximately 600 degrees C. The walls 26, 28, 30, 32, 34, 36 of the housing 16 are water cooled and may have a temperature of approximately 30 degrees C. The microwave radiation may be generated by the microwave energy source 14 and the wafers 12 may be rotated until the annealing process is over at which point the microwave radiation is discontinued and the rotation is stopped.

Some benefits and advantages of the current invention are described with reference to the figures. Referring to FIG. 5, the stack of wafers 12 within the internal chamber 38 generates thermal radiation (heat), as indicated by the arrows pointing away from the wafers 12. Advantageously, the top wall 26, the bottom wall 28, the left side wall 30, and the right side wall 32 each reflect infrared (thermal) radiation, as indicated by the arrows pointing away from the walls 26, 28, 30, 32 and back toward the stack of wafers 12. This configuration provides for faster temperature stabilization and a reduction in energy from the microwave energy source 14. Equally as important, the heat reflected from the walls 26, 28, 30, 32 is always equal or at a lower energy state as compared to the wafers 12.

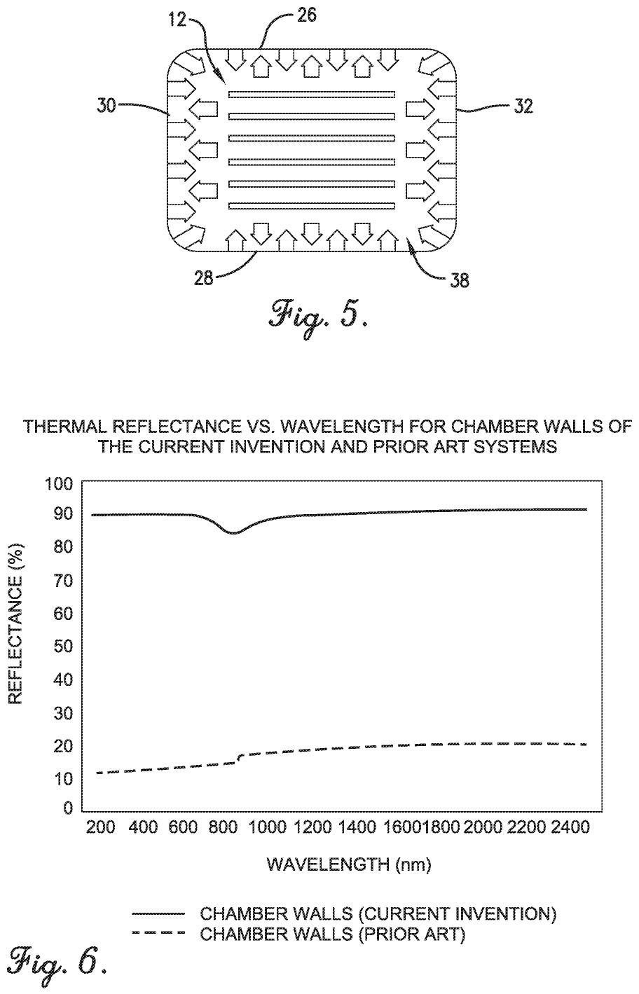

Referring to FIG. 6, a plot of the thermal reflectance of the inner surface of the walls 26, 28, 30, 32, 34, 36 surrounding the internal chamber 38 vs. the wavelength of the radiation waves for the current invention and for prior art systems is shown. As indicated, the inner surface of the walls of prior art systems has a thermal reflectance that is relatively low with a value of approximately 10% to approximately 20% across the range of wavelengths. In contrast, the inner surface of the walls 26, 28, 30, 32, 34, 36 of the current invention has a thermal reflectance that is relatively high with a value of approximately 80% to approximately 90% across the range of wavelengths. The high amount of thermal reflectance of the walls 26, 28, 30, 32, 34, 36 of the current system leads to the improved performance demonstrated in FIG. 5. The high level of infrared reflectance also allows the internal chamber 38 wall to be cooled effectively—avoiding shifts in the single mode field and the impedance matching of the wafers 12 to the microwave energy source 14.

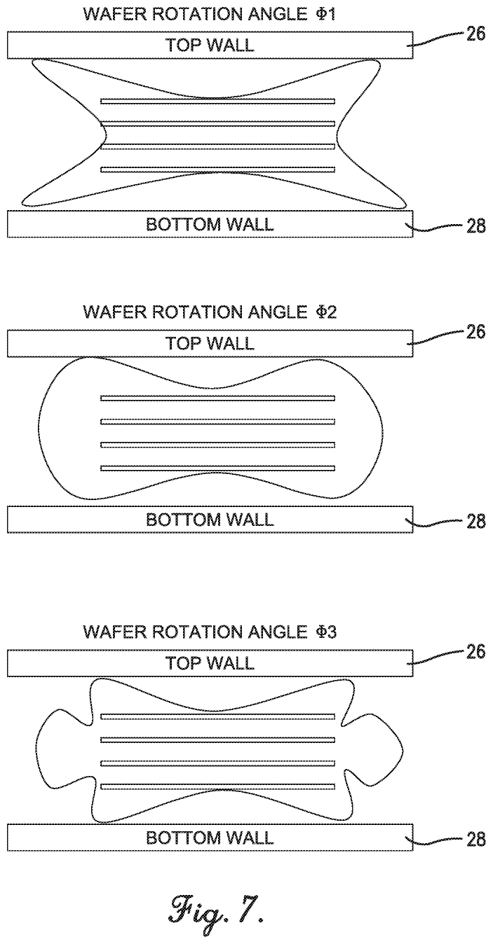

Referring to FIG. 7, a plot of an electric field radiation pattern of the stack of wafers 12 at a rotation angle ϕ with three different values is shown, wherein the rotation angle is an angle through which the plate 42 has been rotated about a vertical axis. In the top plot, the electric field radiation pattern of the stack of wafers 12 at a first rotation angle ϕ1 is shown. In the middle plot, the electric field radiation pattern of the stack of wafers 12 at a second rotation angle ϕ2 is shown. In the bottom plot, the electric field radiation pattern of the stack of wafers 12 at a third rotation angle ϕ3 is shown.

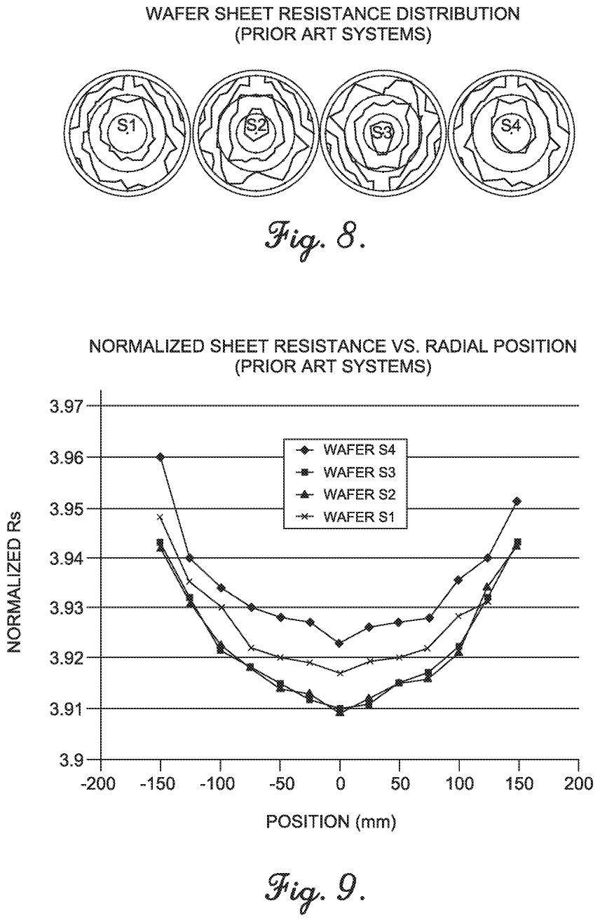

Referring to FIG. 8, a plot of a distribution of a wafer sheet resistance across four wafers, S1-S4, while the wafers are being annealed in a prior art system is shown. Each wafer shows a relatively large variation in the value of the sheet resistance when moving radially outward from the center. The sheet resistance variation may relate to, or vary with, the temperatures of the wafers while being annealed. A large temperature variation across the volume of the wafers leads to a reduction in performance of wafers after annealing.

Referring to FIG. 9, a plot of a normalized sheet resistance (Rs) vs. radial position for four wafers annealed in a prior art system is shown. The wafers have a diameter of 300 mm. The plot shows a relatively large variation in Rs from one edge of each wafer (at −150 mm) to the opposing edge of each wafer (at 150 mm). As mentioned above, this is undesirable.

Referring to FIG. 10, a plot of a distribution of a wafer sheet resistance across four wafers, S1-S4, while the wafers are being annealed in the current invention is shown. Each wafer shows a relatively small variation in the value of the sheet resistance when moving radially outward from the center. This may be an indication of uniform annealing of the wafers, which leads to an improvement in performance of wafers after annealing.

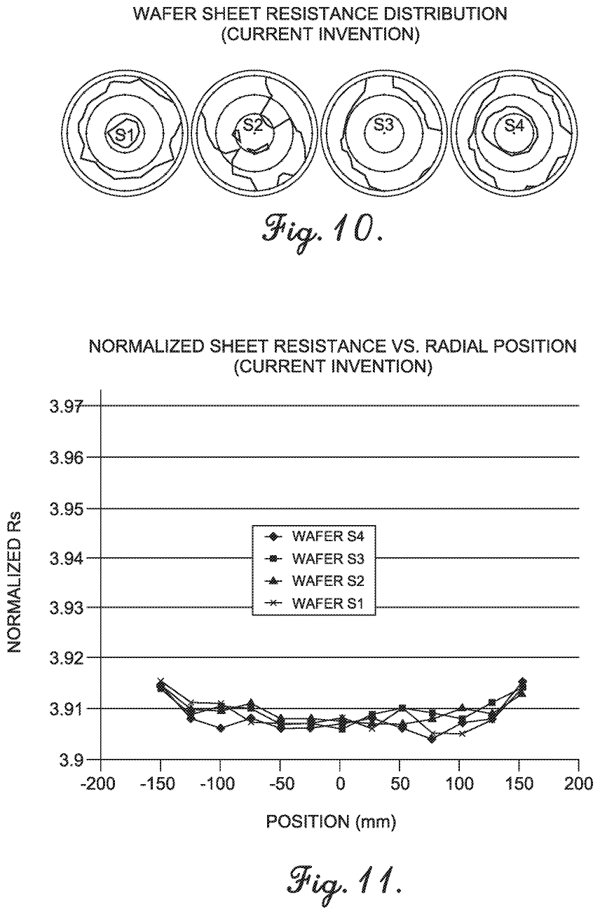

Referring to FIG. 11, a plot of a normalized sheet resistance (Rs) vs. radial position for four wafers annealed in the current invention is shown. The plot shows a relatively small variation in Rs from one edge of each wafer (at −150 mm) to the opposing edge of each wafer (at 150 mm). As mentioned above, this is desirable.

### ADDITIONAL CONSIDERATIONS

Throughout this specification, references to “one embodiment”, “an embodiment”, or “embodiments” mean that the feature or features being referred to are included in at least one embodiment of the technology. Separate references to “one embodiment”, “an embodiment”, or “embodiments” in this description do not necessarily refer to the same embodiment and are also not mutually exclusive unless so stated and/or except as will be readily apparent to those skilled in the art from the description. For example, a feature, structure, act, etc. described in one embodiment may also be included in other embodiments, but is not necessarily included. Thus, the current invention can include a variety of combinations and/or integrations of the embodiments described herein.

Although the present application sets forth a detailed description of numerous different embodiments, it should be understood that the legal scope of the description is defined by the words of the claims set forth at the end of this patent and equivalents. The detailed description is to be construed as exemplary only and does not describe every possible embodiment since describing every possible embodiment would be impractical. Numerous alternative embodiments may be implemented, using either current technology or technology developed after the filing date of this patent, which would still fall within the scope of the claims.

Throughout this specification, plural instances may implement components, operations, or structures described as a single instance. Although individual operations of one or more methods are illustrated and described as separate operations, one or more of the individual operations may be performed concurrently, and nothing requires that the operations be performed in the order illustrated. Structures and functionality presented as separate components in example configurations may be implemented as a combined structure or component. Similarly, structures and functionality presented as a single component may be implemented as separate components. These and other variations, modifications, additions, and improvements fall within the scope of the subject matter herein.

As used herein, the terms “comprises,” “comprising,” “includes,” “including,” “has,” “having” or any other variation thereof, are intended to cover a non-exclusive inclusion. For example, a process, method, article, or apparatus that comprises a list of elements is not necessarily limited to only those elements but may include other elements not expressly listed or inherent to such process, method, article, or apparatus.

The patent claims at the end of this patent application are not intended to be construed under 35 U.S.C. § 112(f) unless traditional means-plus-function language is expressly recited, such as “means for” or “step for” language being explicitly recited in the claim(s).

Although the technology has been described with reference to the embodiments illustrated in the attached drawing figures, it is noted that equivalents may be employed and substitutions made herein without departing from the scope of the technology as recited in the claims.

Having thus described various embodiments of the technology, what is claimed as new and desired to be protected by Letters Patent includes the following:

1. An apparatus for annealing semiconductor integrated circuit wafers, the apparatus comprising:
a microwave energy source configured to generate microwave radiation having a first wavelength; and
a reactor housing configured to receive a plurality of semiconductor integrated circuit wafers simultaneously, the reactor housing including a top wall, a bottom wall, a left side wall, a right side wall, a front wall, and a back wall connected to one another to form a box-shaped internal chamber, each wall being electrically connected to electrical ground and each wall being water cooled, the walls of the internal chamber spaced apart such that the microwave radiation forms a single mode around the semiconductor integrated circuit wafers within the internal chamber.

2. The apparatus of claim 1, further comprising a wafer support structure including a plurality of columns, each column including a plurality of notches, wherein each semiconductor integrated circuit wafer is supported along an edge thereof by one notch of the respective columns.

3. The apparatus of claim 1, wherein the semiconductor integrated circuit wafers are impedance matched to the microwave energy source.

4. The apparatus of claim 1, wherein an inner surface of each wall is thermally reflective and has a polished inner surface.

5. The apparatus of claim 4, wherein the inner surface of each wall has a thermal reflectance of at least 80%.

6. The apparatus of claim 1, wherein an edge where any two adjacent walls intersect is rounded or filleted, and a corner where any three adjacent walls intersect is rounded or filleted.

7. The apparatus of claim 1, wherein a spacing between an inner surface of the top wall and an inner surface of the bottom wall varies according to the first wavelength.

8. The apparatus of claim 1, wherein a spacing between an inner surface of the top wall and an uppermost semiconductor integrated circuit wafer ranges from approximately 12.7 millimeters to approximately 76.2 millimeters, and a spacing between an inner surface of the bottom wall and a lowermost semiconductor integrated circuit wafer ranges from approximately 12.7 millimeters to approximately 76.2 millimeters.

9. The apparatus of claim 1, wherein a combination of the wafers, the top wall, and the bottom wall form a slot plane antenna.

10. The apparatus of claim 1, wherein each wafer is heated directly by the microwave radiation from the microwave energy source.

11. An apparatus for annealing semiconductor integrated circuit wafers, the apparatus comprising:
a microwave energy source configured to generate microwave radiation having a first wavelength; and
a reactor housing configured to receive a plurality of semiconductor integrated circuit wafers simultaneously, the reactor housing including a top wall, a bottom wall, a left side wall, a right side wall, a front wall, and a back wall connected to one another to form a box-shaped internal chamber, each wall being electrically connected to electrical ground and each wall being water cooled, wherein each wafer is heated directly by the microwave radiation from the microwave energy source.

12. The apparatus of claim 11, further comprising a wafer support structure including a plurality of columns, each column including a plurality of notches, wherein each semiconductor integrated circuit wafer is supported along an edge thereof by one notch of the respective columns.

13. The apparatus of claim 11, wherein the semiconductor integrated circuit wafers are impedance matched to the microwave energy source.

14. The apparatus of claim 11, wherein an inner surface of each wall is thermally reflective and has a polished inner surface.

15. The apparatus of claim 14, wherein the inner surface of each wall has a thermal reflectance of at least 80%.

16. The apparatus of claim 11, wherein an edge where any two adjacent walls intersect is rounded or filleted, and a corner where any three adjacent walls intersect is rounded or filleted.

17. The apparatus of claim 11, wherein a spacing between an inner surface of the top wall and an inner surface of the bottom wall varies according to the first wavelength.

18. The apparatus of claim 11, wherein a spacing between an inner surface of the top wall and an uppermost semiconductor integrated circuit wafer ranges from approximately 12.7 millimeters to approximately 76.2 millimeters, and a spacing between an inner surface of the bottom wall and a lowermost semiconductor integrated circuit wafer ranges from approximately 12.7 millimeters to approximately 76.2 millimeters.

19. The apparatus of claim 11, wherein a combination of the wafers, the top wall, and the bottom wall form a slot plane antenna.

20. An apparatus for annealing semiconductor integrated circuit wafers, the apparatus comprising:
a microwave energy source configured to generate microwave radiation having a first wavelength; and
a reactor housing configured to receive a plurality of semiconductor integrated circuit wafers simultaneously, the reactor housing including a top wall, a bottom wall, a left side wall, a right side wall, a front wall, and a back wall connected to one another to form a box-shaped internal chamber, each wall being electrically connected to electrical ground and each wall being water cooled, the walls of the internal chamber spaced apart such that the microwave radiation forms a single mode within the internal chamber, wherein each wafer is heated directly by the microwave radiation from the microwave energy source, and
a wafer support structure including a plurality of columns, each column including a plurality of notches, wherein each semiconductor integrated circuit wafer is supported along an edge thereof by one notch of the respective columns.
